(19) United States
(12) Patent Application Publication
(10) Pub. No.: US 2024/0053523 A1
(43) Pub. Date: Feb. 15, 2024

(54) POLARIZING PLATE AND OPTICAL DISPLAY APPARATUS COMPRISING THE SAME

(71) Applicant: SAMSUNG SDI CO., LTD., Yongin-si (KR)

(72) Inventors: Sung Man CHO, Suwon-si (KR); Seung Jun LEE, Suwon-si (KR); Seon Oh HWANG, Suwon-si (KR); Kwang Ho SHIN, Suwon-si (KR); Han Saem KANG, Suwon-si (KR); Do Won KIM, Suwon-si (KR)

(21) Appl. No.: 18/353,480

(22) Filed: Jul. 17, 2023

(30) Foreign Application Priority Data
Aug. 9, 2022 (KR) 10-2022-0098977

(51) Int. Cl. G02B 5/30; G02B 1/14

(52) U.S. Cl. CPC G02B 5/305; G02B 1/14

(57) ABSTRACT

A polarizing plate and an optical display apparatus including the same are disclosed. A polarizing plate includes a polarizer and a protective film formed on a surface of the polarizer, wherein the polarizer has a thickness of 10 μm or less and the polarizing plate has a coefficient of thermal expansion (CTE) of 100 μm/(m·° C.) or less, as measured in a machine direction of the polarizer after application of heat shock conditions.

### CROSS-REFERENCE TO RELATED APPLICATION

This application claims priority to and the benefit of Korean Patent Application No. 10-2022-0098977, filed on Aug. 9, 2022 in the Korean Intellectual Property Office, the entire disclosure of which is incorporated herein by reference.

### BACKGROUND

### 1. Field

Aspects of embodiments of the present invention relate to a polarizing plate and an optical display apparatus including the same.

### 2. Description of the Related Art

In an optical display apparatus, a polarizing plate provides not only a polarization function but also a light transmission function allowing an image sensor, such as a camera and the like, to record video and photograph an image. For the light transmission function, the polarizing plate is required to have a hole that corresponds to a non-polarization region.

The hole may be formed by a physical method, such as punching and the like, a chemical method using an acid and/or a base, or an optical method using light, such as a laser beam and the like. Among these methods, the physical method is a cost-effective process of forming an opening in a region of the polarizing plate by punching the polarizing plate. In the optical display apparatus, the polarizing plate may be stacked on another optical device via an adhesive layer, for example, an optically clear adhesive (OCA) and the like. The hole formed by the physical method provides a step corresponding to a thickness in the polarizing plate. As a result, bubbles may enter the hole upon attachment of the adhesive layer to the polarizing plate, thereby causing observation of the bubbles.

A polarizer is fabricated by stretching a polyvinyl alcohol-based film in the machine direction and in a high stretching ratio. Thus, when the polarizing plate shrinks due to heat shock and the like, the hole generates cracks in the polarizing plate to allow bubbles to be more easily observed with the naked eye when the bubbles are entered in the hole, thereby causing significant deterioration in usability of the polarizing plate.

To prevent or substantially prevent observation of bubbles, a polarizer produced from a polyvinyl alcohol-based film having certain properties may be used. However, it is confirmed that this method cannot be used when the size of the hole is remarkably reduced. In recent years, as the optical display apparatus is gradually reduced in size and the size of the hole is gradually reduced so that the hole is not to be observed from the outside, there is a need for a technique for preventing or substantially preventing observation of bubbles in a hole formed in a polarizing plate and having a remarkably small diameter.

The background technique of the present invention is disclosed in Korean Patent Laid-open Publication No. 10-2013-0078606 and the like.

### SUMMARY

According to an aspect of embodiments of the present invention, a polarizing plate is provided that prevents or substantially prevents generation of bubbles inside a hole, which is formed to have a small diameter in the polarizing plate, and/or minimizes or reduces observation of bubbles, if any, having entered the hole, when the polarizing plate is laminated to an adhesive film after formation of the hole having the small diameter.

According to another aspect of embodiments of the present invention, a polarizing plate is provided that includes a thin thickness polarizer and prevents or substantially prevents generation of bubbles inside a hole, which is formed to have a small diameter in the polarizing plate, and/or minimizes reduces observation of bubbles, if any, having entered the hole, when the polarizing plate is laminated to an adhesive film after formation of the hole having the small diameter.

According to another aspect of embodiments of the present invention, a polarizing plate is provided that prevents or substantially prevents generation of cracks after application of heat shock thereto, regardless of formation of a hole having a small diameter therein.

According to another aspect of embodiments of the present invention, a polarizing plate is provided that provides thickness reduction.

An aspect of embodiments of the present invention relates to a polarizing plate.

According to one or more embodiments, a polarizing plate includes a polarizer and a protective film on a surface of the polarizer, wherein the polarizer has a thickness of 10 μm or less and the polarizing plate has a coefficient of thermal expansion (CTE) of 100 μm/(m·° C.) or less, as measured in a machine direction of the polarizer after the polarizing plate is left under the following heat shock conditions: heating the polarizing plate from 25° C. to 80° C. at a heating rate of 5° C./min; cooling the polarizing plate from 80° C. to −40° C. at a cooling rate of 5° C./min; heating the polarizing plate from −40° C. to 80° C. at a heating rate of 5° C./min; cooling the polarizing plate from 80° C. to −40° C. at a cooling rate of 5° C./min; heating the polarizing plate from −40° C. to 80° C. at a heating rate of 5° C./min; and cooling the polarizing plate from 80° C. to −40° C. at a cooling rate of 5° C./min.

In one or more embodiments, the polarizer may include a polyvinyl alcohol-based film and the polyvinyl alcohol-based film may contain both a hydrophilic functional group and a hydrophobic functional group.

In one or more embodiments, the polarizer may include a polyvinyl alcohol-based film, and the polyvinyl alcohol-based film may have a softening point of 66° C. to 70° C.

In one or more embodiments, the coefficient of thermal expansion of the polarizer measured under the heat shock conditions may be in a range of 50% to 250% of the coefficient of thermal expansion of the polarizing plate measured under the heat shock conditions.

In one or more embodiments, the polarizer may have a boric acid content of 15 wt % to 30 wt %.

In one or more embodiments, the polarizing plate may have a coefficient of thermal expansion of 20 μm/(m·° C.) or less, as measured before the polarizing plate is left under the heat shock conditions.

In one or more embodiments, the protective film may have a coefficient of thermal expansion of 40 μm/(m·° C.) or more, as measured after the polarizing plate is left under the heat shock conditions.

In one or more embodiments, the protective film may include a triacetylcellulose, polyethylene terephthalate, or amorphous cyclic polyolefin resin film.

In one or more embodiments, the polarizing plate may further include an adhesive layer formed on a surface of the protective film, the adhesive layer having a storage modulus at 100° C. of 40 kPa or more and satisfying the following Formula 1:

0<|G2−G1|/G1≤0.1, Formula 1

where, in Formula 1, G1 is storage modulus (unit: kPa) of the adhesive layer at 100° C., and G2 is storage modulus (unit: kPa) of the adhesive layer at 120° C.

In one or more embodiments, the adhesive layer may have a storage modulus at 120° C. of 40 kPa or more.

In one or more embodiments, the adhesive layer may include a cured product of a composition including a (meth)acrylic-based copolymer, an isocyanate-based curing agent, and a metal chelate-based curing agent.

In one or more embodiments, the (meth)acrylic-based copolymer may be a copolymer of a monomer mixture including 40 wt % to 95 wt % of an alkyl group-containing (meth)acrylic-based monomer, 0.01 wt % to 20 wt % of a crosslinkable functional group-containing (meth)acrylic-based monomer, 1 wt % to 40 wt % of a (meth)acrylic-based monomer having a homopolymer glass transition temperature (Tg) of 0° C. or more, and 1 wt % to 35 wt % of an aromatic group-containing (meth)acrylic-based monomer.

In one or more embodiments, the composition may include 100 parts by weight of the (meth)acrylic-based copolymer, 0.01 parts by weight to 5 parts by weight of the isocyanate-based curing agent, and 0.01 parts by weight to 5 parts by weight of the metal chelate-based curing agent.

In one or more embodiments, a hole may be formed in at least a region of the polarizing plate in an in-plane direction to penetrate through the polarizing plate in a thickness direction thereof.

In one or more embodiments, the hole may have a diameter of 4 mm or less.

Another aspect of embodiments of the present invention relates to an optical display apparatus.

In one or more embodiments, an optical display apparatus includes the polarizing plate according to an embodiment of the present invention.

An aspect of the present invention provides a polarizing plate that prevents or substantially prevents generation of bubbles inside a hole, which is formed to have a small diameter in the polarizing plate, and/or minimizes or reduces observation of bubbles, if any, having entered the hole, when the polarizing plate is laminated to an adhesive film after formation of the hole having the small diameter.

Another aspect of the present invention provides a polarizing plate that includes a thin thickness polarizer and prevents or substantially prevents generation of bubbles inside a hole, which is formed to have a small diameter in the polarizing plate, and/or minimizes or reduces observation of bubbles, if any, having entered the hole, when the polarizing plate is laminated to an adhesive film after formation of the hole having the small diameter.

Another aspect of the present invention provides a polarizing plate that prevents or substantially prevents generation of cracks after application of heat shock thereto, regardless of formation of a hole having a small diameter therein.

Another aspect of the present invention provides a polarizing plate that provides a thickness reduction.

### BRIEF DESCRIPTION OF THE DRAWINGS

FIG. 1 is a graph depicting a TMA measurement result of a polarizing plate according to an embodiment of the present invention after the polarizing plate is left under heat shock conditions.

FIG. 2 is a cross-sectional view of a polarizing plate according to an embodiment of the present invention after formation of a hole in the polarizing plate.

FIG. 3 is a cross-sectional view of a polarizing plate according to another embodiment of the present invention after formation of a hole in the polarizing plate.

FIG. 4 is a cross-sectional view of a specimen for evaluation of bubble generation in a hole.

### DETAILED DESCRIPTION

Herein, some embodiments of the present invention will be described in further detail with reference to the accompanying drawings such that the present invention can be easily implemented by those skilled in the art. It is to be understood, however, that the present invention may be embodied in different ways and is not limited to the following embodiments.

Terms used herein are used to describe example implementations and are not intended to limit the present invention. Singular expressions include plural expressions unless the context clearly dictates otherwise.

Herein, “coefficient of thermal expansion” means a linear coefficient of thermal expansion obtained through thermomechanical analysis (TMA, Q400, TA Instrument) with respect to a measurement target. The coefficient of thermal expansion may be measured in the same manner before and after application of heat shock to the measurement target.

When a target for measurement of the coefficient of thermal expansion is a polarizing plate including a polarizer and a protective film formed on at least one surface of the polarizer, a sample of the polarizing plate is prepared to have a size of 8 mm×5 mm (machine direction (MD) of the polarizer×transverse direction (TD) of the polarizer). Then, the sample is heated from 25° C. to 80° C. at a heating rate of 5° C./min under a load of 0.02 N to 0.05 N applied in a stretching direction of the polarizer (in the MD of the polarizer) under a nitrogen atmosphere, thus to measure the coefficient of thermal expansion.

Herein, “heat shock conditions” are as follows: heating the polarizing plate from 25° C. to 80° C. at a heating rate of 5° C./min; cooling the polarizing plate from 80° C. to −40° C. at a cooling rate of 5° C./min; heating the polarizing plate from −40° C. to 80° C. at a heating rate of 5° C./min; cooling the polarizing plate from 80° C. to −40° C. at a cooling rate of 5° C./min; heating the polarizing plate from −40° C. to 80° C. at a heating rate of 5° C./min; and cooling the polarizing plate from 80° C. to −40° C. at a cooling rate of 5° C./min.

A target for measurement of the coefficient of thermal expansion may be a polarizing plate, a protective film, or a polarizer. When the target for measurement of the coefficient of thermal expansion is a protective film or a polarizer, the coefficient of thermal expansion thereof may be measured using substantially the same method as in measurement of the coefficient of thermal expansion of the polarizing plate.

As used herein to represent a specific numerical range, “X to Y” means “greater than or equal to X and less than or equal to Y (X≤ and ≤Y).”

Herein, “(meth)acryl” refers to acryl and/or methacryl.

The inventors of the present invention have developed a polarizing plate that prevents or substantially prevents generation of bubbles inside a hole, which is formed to have a small diameter in the polarizing plate by a physical method, for example, by punching, and/or minimizes or reduces observation of bubbles, if any, having entered the hole, when the polarizing plate is laminated to an adhesive film after formation of the hole having the small diameter.

The inventors of the present invention have developed a polarizing plate that includes a polarizer having a thickness of 10 μm or less and prevents or substantially prevents generation of bubbles inside a hole, which is formed to have a small diameter in the polarizing plate by a physical method, for example, by punching, and/or minimizes or reduces observation of the bubbles, if any, having entered the hole, when the polarizing plate is laminated to an adhesive film after formation of the hole and is left under the heat shock conditions.

The inventors of the present invention have developed a polarizing plate that prevents or substantially prevents generation of cracks under the heat shock conditions, regardless of formation of a hole having a small diameter.

The inventors of the present invention have developed a polarizing plate that includes an adhesive layer and prevents or substantially prevents generation of bubbles around a hole, which is formed to have a small diameter in the polarizing plate by a physical method, for example, by punching, and/or prevents or substantially prevents observation of the bubbles, if any, having entered the hole, while preventing or substantially preventing crack generation around the hole due to shrinkage of the hole, both before application of heat shock to the polarizing plate and after application of heat shock thereto, when the polarizing plate formed with the hole is laminated to the adhesive film.

In one or more embodiments, a hole may be formed in at least a region of the polarizing plate in an in-plane direction thereof to penetrate through the polarizing plate in a thickness direction thereof.

In one or more embodiments, the hole may be formed to completely penetrate through the polarizing plate in the thickness direction of the polarizing plate. The hole may have a diameter of 4 mm or less, for example, greater than 0 mm to 4 mm.

A ratio (area ratio) of an area of the hole to a total area of the polarizing plate may be in a range from 0.03% to 0.5%, and, in an embodiment, 0.03% to 0.48%. Within this range, the polarizing plate can perform a light transmission function through the hole. The hole may have a circular, elliptical, or semicircular cross-section, without being limited thereto.

Herein, “bubbles” means air bubbles having a diameter of 100 μm or less. When the bubbles have a size of 100 μm or less, the bubbles are blocked by a black matrix around the hole in an actual display and may not be observed by a user with the naked eye.

Herein, a polarizing plate according to an embodiment of the present invention will be described.

The polarizing plate includes a polarizer and a protective film formed on at least one surface of the polarizer. In an embodiment, the polarizing plate may include a polarizer, a first protective film formed on an upper surface of the polarizer, and a second protective film formed on a lower surface of the polarizer.

The polarizing plate may be applied to an optical display apparatus after formation of a hole in the polarizing plate. The hole may correspond to a non-image display region and a region of the polarizing plate other than the hole may correspond to an image display region. FIG. 2 is a cross-sectional view of a polarizing plate according to an embodiment of the present invention.

Referring to FIG. 2, in an embodiment, the polarizing plate includes a polarizer 10, a first protective film 20 stacked on an upper surface of the polarizer 10, and a second protective film 30 stacked on a lower surface of the polarizer 10, in which a hole 40 is formed in a region of the polarizing plate in the in-plane direction thereof. In an embodiment, the hole 40 may be formed perpendicular to a surface of the polarizing plate (to an upper or lower surface of the polarizing plate) in the thickness direction of the polarizing plate.

In an embodiment, the polarizer may have a thickness of 10 μm or less. Within this range, the polarizing plate may allow easy formation of a smooth vertical hole cross-section in formation of a hole having a small diameter through punching and exhibit good step embedding properties. Thus, generation or observation of bubbles around the hole may be suppressed, even when the polarizing plate is laminated to an adhesive layer after formation of the hole. In an embodiment, the polarizer may have a thickness of greater than 0 μm, 1 μm, 2 μm, 3 μm, 4 μm, 5 μm, 6 μm, 7 μm, 8 μm, 9 μm, or 10 μm, for example, greater than 0 μm to 9 μm, and, in an embodiment, 0.5 μm to 7 μm.

The inventors of the present invention confirmed that a polarizing plate including a polarizer having a thickness of 10 μm or less can suppress generation and observation of bubbles, when the polarizing plate is laminated to an adhesive layer after formation of a hole having a small diameter in the polarizing plate. However, after the polarizing plate is laminated to an adhesive layer, the bubbles were generated and observed around the hole due to shrinkage of the hole together with generation of cracks and light leakage not only around the hole but also over the entirety of the polarizing plate upon application of heat shock under heat shock conditions. In addition, the inventors of the present invention confirmed that, although the polarizing plate not formed with a hole could prevent crack generation or light leakage under the same heat shock conditions, crack generation and light leakage occurred around the hole due to shrinkage of the hole under the heat shock conditions after formation of the hole in the polarizing plate. Since the polarizer is formed through uniaxial stretching in the machine direction of the polarizer and in high stretching ratio, the polarizing plate formed with a hole may have a reduced capability to suppress shrinkage due to the hole under the heat shock conditions.

Accordingly, the inventors of the present invention developed a polarizing plate having a coefficient of thermal expansion of 100 μm/(m·° C.) or less, as measured after application of heat shock under the heat shock conditions. Within this range of the coefficient of thermal expansion, even with a polarizer having a thickness of 10 μm or less, the polarizing plate can prevent or substantially prevent generation of bubbles around a hole having a small diameter and/or can prevent or substantially prevent observation of the bubbles, if any, while preventing or substantially preventing generation of cracks around the hole due to shrinkage of the hole, upon application of heat shock, after the polarizing plate is formed with the hole and is laminated to an adhesive film.

In an embodiment, the polarizing plate may have a coefficient of thermal expansion of 1, 5, 10, 15, 20, 25, 30, 35, 40, 45, 50, 55, 60, 65, 70, 75, 80, 85, 90, 95, or 100 μm/(m·° C.), as measured after the polarizing plate is left under the heat shock conditions. For example, the polarizing plate may have a coefficient of thermal expansion of 70 μm/(m·° C.) to 100 μm/(m·° C.), and, in an embodiment, 80 μm/(m·° C.) to 100 μm/(m·° C.), as measured after the polarizing plate is left under the heat shock conditions. Within this range, the polarizing plate can realize not only the above effects, but also a polarization function and easy manufacture.

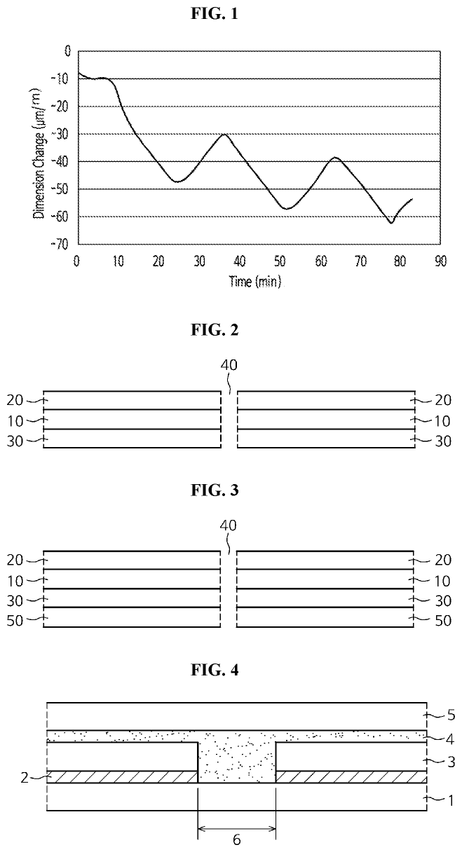

FIG. 1 is a graph depicting a TMA measurement result of a polarizing plate according to an embodiment of the present invention after the polarizing plate is left under heat shock conditions. Referring to FIG. 1, it can be seen that the polarizing plate can have non-uniform dimensional change when exposed to heat shock. It can be seen that, since the degree of dimensional change of the polarizing plate varies according to a temperature change between high temperature and low temperature, it may be difficult to anticipate the coefficient of thermal expansion only from the coefficient of thermal expansion measured at high temperature.

A coefficient of thermal expansion of 100 μm/(m·° C.) or less measured after the polarizing plate is left under heat shock conditions can be achieved through adjustment in thickness of a polarizer in the polarizing plate, a type of a polyvinyl alcohol-based film for the polarizer, and various factors, such as a stretching ratio, a stretching temperature, and the like, in a process of manufacturing a polarizer using a selected polyvinyl alcohol-based film.

In an embodiment, the polarizing plate may have a coefficient of thermal expansion of 20 μm/(m·° C.) or less, for example, greater than 0, 1, 2, 3, 4, 5, 6, 7, 8, 9, 10, 11, 12, 13, 14, 15, 16, 17, 18, 19, or 20 μm/(m·° C.), for example, greater than 0 μm/(m·° C.) to 20 μm/(m·° C.), and, in an embodiment, 5 μm/(m·° C.) to 20 μm/(m·° C.), as measured before the polarizing plate is left under the heat shock conditions.

The polarizing plate according to the present invention may include a polyvinyl alcohol-based film described below. The polarizing plate according to the present invention may include a polarizer prepared from the polyvinyl alcohol-based film using the process described below. With this structure, the polarizing plate can easily ensure a coefficient of thermal expansion of 100 μm/(m·° C.) or less, as measured after the polarizing plate is left under the heat shock conditions.

The polyvinyl alcohol-based film may contain a hydrophilic functional group and a hydrophobic functional group. The hydrophobic functional group may be additionally provided to the polyvinyl alcohol-based film, together with a hydroxyl (OH) group, which is the hydrophilic functional group. By manufacturing the polarizer using the polyvinyl alcohol-based film containing both the hydrophilic functional group and the hydrophobic functional group through a process described below, the polarizing plate according to the present invention can easily achieve a coefficient of thermal expansion of 100 μm/(m·° C.) or less.

At least one hydrophobic functional group may be present in at least one of a main chain and a side chain of a polyvinyl alcohol-based resin constituting the polyvinyl alcohol-based film. Here, the main chain means a portion forming a main backbone of the polyvinyl alcohol-based resin and the side chain means a side backbone connected to the main chain. In an embodiment, the hydrophobic functional group may be present in the main chain of the polyvinyl alcohol-based resin.

The polyvinyl alcohol-based resin containing the hydrophilic functional group and the hydrophobic functional group may be prepared by polymerizing at least one vinyl ester monomer, such as vinyl acetate, vinyl formate, vinyl propionate, vinyl butyrate, vinyl pivalate, isopropenyl acetate, and the like, and a monomer providing the hydrophobic functional group. In an embodiment, the vinyl ester monomer may include vinyl acetate. The monomer providing the hydrophobic functional group may include any of monomers capable of providing a hydrocarbon repeat unit, such as ethylene, propylene, and the like.

In an embodiment, the polyvinyl alcohol-based film may have a softening point of 66° C. to 70° C., for example, 66° C., 67° C., 68° C., 69° C., or 70° C., for example, 67° C. to 69° C. Within this range, the polyvinyl alcohol-based film can avoid melting and fracture in the stretching process and can easily form the polarizer according to the present invention.

In an embodiment, the polyvinyl alcohol-based film may have a tensile strength of 95 MPa to 105 MPa, for example, 95 MPa, 96 MPa, 97 MPa, 98 MPa, 99 MPa, 100 MPa, 101 MPa, 102 MPa, 103 MPa, 104 MPa, or 105 MPa, and, in an embodiment, 97 MPa to 99 MPa, as measured in the machine direction thereof. Within this range, the polyvinyl alcohol-based film can avoid melting and fracture in the stretching process, can provide a high degree of polarization through effective alignment of polyvinyl alcohol molecule chains, and can easily form the polarizer according to the present invention. Tensile strength of the polyvinyl alcohol-based film may be measured at 25° C. using a universal testing machine (UTM) in accordance with ASTM D882.

In an embodiment, the polyvinyl alcohol-based film may have a thickness of 50 μm or less, for example, 10 μm to 50 μm. Within this range, the polyvinyl alcohol-based film can avoid melting and fracture in the stretching process.

The polyvinyl alcohol-based film may be a TS-#2000 PVA film (Nippon Kuraray Co., Ltd.).

The polarizer may be manufactured from the polyvinyl alcohol-based film by sequentially performing a dyeing process, a stretching process, and a crosslinking process, which are described below. As a result, the polarizing plate can easily ensure a coefficient of thermal expansion of 100 μm/(m·° C.) or less, as measured after the polarizing plate is left under the heat shock conditions.

The dyeing process may include treatment of the polyvinyl alcohol-based film in a dyeing bath containing a dichroic material. In the dyeing process, the polyvinyl alcohol-based film may be dipped in the dyeing bath containing a dichroic material. The dyeing bath may contain a dyeing solution (for example, a dyeing aqueous solution) containing the dichroic material and a boron compound. As the dyeing bath contains both the dichroic material and the boron compound, the polyvinyl alcohol-based film can be dyed in the dyeing bath and may not have fracture upon stretching under stretching conditions described below.

The dichroic material may include iodide and include at least one selected from among potassium iodide, hydrogen iodide, lithium iodide, sodium iodide, zinc iodide, aluminum iodide, lead iodide, and copper iodide. In an embodiment, the dichroic material may be present in an amount of 0.5 mol/ml to 10 mol/ml, and, in an embodiment, 0.5 mol/ml to 5 mol/ml, in the dyeing bath, and, in an embodiment, in the dyeing solution. Within this range, the polyvinyl alcohol-based film can be uniformly dyed.

The boron compound can assist in prevention of melting and fracture of the polyvinyl alcohol-based film, when the polyvinyl alcohol-based film is stretched. The boron compound can assist in prevention of melting and fracture of the polyvinyl alcohol-based film, when the polyvinyl alcohol-based film is stretched in a high stretching ratio at high temperature after the dyeing process.

The boron compound may include at least one of boric acid and borax. In an embodiment, the boron compound may be present in an amount of 0.1 wt % to 5 wt %, and, in an embodiment, 0.3 wt % to 3 wt %, in the dyeing bath, and, in an embodiment, in the dyeing solution. Within this range, the polyvinyl alcohol-based film can avoid melting and fracture in the stretching process and can achieve high reliability.

In an embodiment, the dyeing solution may have a temperature of 20° C. to 50° C., and, in an embodiment, 25° C. to 40° C. In the dyeing process, the polyvinyl alcohol-based film may be dipped in the dyeing bath for 30 seconds to 120 seconds, and, in an embodiment, 40 seconds to 80 seconds.

In an embodiment, the stretching process may include stretching the dyed polyvinyl alcohol-based film to a stretching ratio of 5.7 times or more, for example, 5.7 times to 7 times, of an initial length thereof, at a stretching temperature of 57° C. or more, for example, 57° C. to 65° C. A typical polyvinyl alcohol-based film cannot form the polarizer due to melting and/or fracture of the polyvinyl alcohol-based film, when it was stretched in this stretching ratio at this temperature.

The stretching process may be realized by one of wet stretching and dry stretching. In an embodiment, in order to use the boron compound in the stretching process, the stretching process may include wet stretching. Wet stretching may include uniaxially stretching the polyvinyl alcohol-based film in the machine direction thereof in an aqueous solution containing a boron compound.

The boron compound may include at least one of boric acid and borax, and, in an embodiment, boric acid. In an embodiment, the boron compound may be present in an amount of 0.5 wt % to 10 wt %, and, in an embodiment, 1 wt % to 5 wt %, in a stretching bath, and, in an embodiment, in a stretching aqueous solution. Within this range, the polyvinyl alcohol-based film can avoid melting and fracture in the stretching process and can achieve high reliability.

The crosslinking process may allow strong adsorption of the dichroic material to the polyvinyl alcohol-based film subjected to the stretching process. A crosslinking solution for the crosslinking process may include a boron compound. The boron compound can assist in strong adsorption of the dichroic compound while improving reliability, even when the polarizer is left under the heat shock conditions.

The boron compound may include at least one of boric acid and borax. In an embodiment, the boron compound may be present in an amount of 0.5 wt % to 10 wt %, and, in an embodiment, 1 wt % to 5 wt %, in a crosslinking bath, and, in an embodiment, in a crosslinking aqueous solution. Within this range, the polyvinyl alcohol-based film can avoid melting and fracture in the stretching process and can achieve high reliability. The crosslinking aqueous solution may have a temperature of 20° C. to 50° C., and, in an embodiment, 25° C. to 40° C. In the crosslinking process, the polyvinyl alcohol-based film may be dipped in the crosslinking bath for 30 seconds to 120 seconds, and, in an embodiment, 40 seconds to 80 seconds.

Before the dyeing process, the polyvinyl alcohol-based film may be further subjected to at least one of a washing process and a swelling process.

The washing process may refer to a process of washing the polyvinyl alcohol-based film with water to remove foreign matter from the polyvinyl alcohol-based film.

In the swelling process, the polyvinyl alcohol-based film may be dipped in a swelling bath at a certain temperature (e.g., a predetermined temperature) to facilitate dyeing of the dichroic material and the stretching process. The swelling process may include swelling treatment at 15° C. to 35° C., and, in an embodiment, 20° C. to 30° C., for 30 seconds to 50 seconds.

After the crosslinking process, the polyvinyl alcohol-based film may be further subjected to a color correction process. Color correction may serve to improve durability of the polyvinyl alcohol-based film. A color correction bath may include a color correction solution containing greater than 0 wt % to 10 wt %, and, in an embodiment, 1 wt % to 5 wt %, of potassium iodide. The color correction solution may have a temperature of 20° C. to 50° C., and, in an embodiment, 25° C. to 40° C. Color correction may be performed by dipping the polyvinyl alcohol-based film in the color correction bath for 5 seconds to 50 seconds, and, in an embodiment, 5 seconds to 20 seconds.

The coefficient of thermal expansion of the polarizer measured after the polarizing plate is left under the heat shock conditions may be the same as or different from the coefficient of thermal expansion of the polarizing plate measured after the polarizing plate is left under the heat shock conditions.

In an embodiment, the coefficient of thermal expansion of the polarizer after the polarizing plate is left under the heat shock conditions may be 50% to 250%, for example, 50%, 60%, 70%, 80%, 90%, 100%, 110%, 120%, 130%, 140%, 150%, 160%, 170%, 180%, 190%, 200%, 210%, 220%, 230%, 240%, or 250%, and, in an embodiment, 130% to 170%, of the coefficient of thermal expansion of the polarizing plate measured after the polarizing plate is left under the heat shock conditions. Within this range, the polarizing plate can easily realize the effects of the present invention while allowing adjustment of the protective film and a bonding layer.

In the polarizer, boric acid may be present in an amount of 15 wt % to 30 wt %, for example, 15%, 16%, 17%, 18%, 19%, 20%, 21%, 22%, 23%, 24%, 25%, 26%, 27%, 28%, 29%, or 30 wt %, and, in an embodiment, 17 wt % to 27 wt %, and, in an embodiment, 20 wt % to 24 wt %. Within this range, the polarizing plate can easily realize the effects of the present invention, even with a thin thickness polarizer having a thickness of 10 μm or less.

The content of boric acid in the polarizer may be calculated by heating 1 g of the polarizer and 50 g of deionized water in a beaker until the polarizer is completely dissolved, mixing the obtained solution with 10 g of a mannitol solution (mannitol:diluted water=1:7, weight ratio), and measuring the content of boric acid through titration of the mixture with a 0.1 N aqueous NaOH solution, followed by calculating the weight ratio of boric acid to the polarizer, without being limited thereto.

### First Protective Film

The first protective film may be stacked on the upper surface of the polarizer to protect the polarizer while improving mechanical strength of the polarizing plate. The first protective film may include an optically transparent protective film.

The first protective film may have a coefficient of thermal expansion of 40 μm/(m·° C.) or more, for example, 40, 45, 50, 55, 60, 65, 70, 75, 80, 85, 90, 95, 100, 105, 110, 115, 120, 125, 130, 135, or 140 μm/(m·° C.), for example, 50 μm/(m·° C.) to 140 μm/(m·° C.), as measured after the polarizing plate is left under the heat shock conditions. Within this range, the first protective film may not affect the effects according to the present invention or increase the coefficient of thermal expansion of the polarizing plate.

The coefficient of thermal expansion of the first protective film may be realized by changing a resin for the protective film and melting and extrusion conditions upon formation of the protective film using the resin.

In an embodiment, the first protective film may be formed through melting and extrusion of an optically transparent resin. In an embodiment, a stretching process may be further performed. The resin may include at least one selected from among cellulose ester-based resins including triacetylcellulose and the like, cyclic polyolefin-based resins including amorphous cyclic olefin polymer (COP) and the like, polycarbonate-based resins, polyester-based resins including polyethylene terephthalate (PET) and the like, polyether sulfone-based resins, polysulfone-based resins, polyamide-based resins, polyimide-based resins, non-cyclic polyolefin-based resins, poly(acrylate)-based resins including a poly(methyl methacrylate) resin and the like, polyvinyl alcohol-based resins, a polyvinyl chloride-based resins, and polyvinylidene chloride-based resin.

In an embodiment, the first protective film may have a thickness of 5 μm to 200 μm, and, in an embodiment, 15 μm to 40 μm. Within this range, the first protective film can be used in the polarizing plate.

A functional coating layer, for example, any of a hard coating layer, an anti-fingerprint layer, an antireflection layer, and the like, may be further formed on an upper surface of the first protective film.

### Second Protective Film

The second protective film may be stacked on a lower surface of the polarizer to protect the polarizer while improving mechanical strength of the polarizing plate. The second protective film may include a film formed of the same resin as the first protective film or a different resin than the first protective film.

In an embodiment, when the first protective film is a cellulose ester-based resin film including triacetylcellulose and the like, the second protective film may be a cellulose ester-based resin film including triacetylcellulose and the like.

In another embodiment, when the first protective film is a polyester-based resin including polyethylene terephthalate (PET), the second protective film may be a cyclic polyolefin-based resin including an amorphous cyclic olefin polymer (COP) and the like or a cellulose ester-based resin film including triacetylcellulose and the like.

The second protective film may have the same thickness as the first protective film or a different thickness than the first protective film.

In an embodiment, the second protective film may have a coefficient of thermal expansion of 40 μm/(m·° C.) or more, for example, 40, 45, 50, 55, 60, 65, 70, 75, 80, 85, 90, 95, 100, 105, 110, 115, 120, 125, 130, 135, or 140 μm/(m·° C.), for example, 50 μm/(m·° C.) to 140 μm/(m·° C.), as measured after the polarizing plate is left under the heat shock conditions. Within this range, the second protective film may not affect the effects according to the present invention or increase the coefficient of thermal expansion of the polarizing plate.

In the polarizing plate, each of the first protective film and the second protective film may be bonded to the polarizer via a bonding layer. The bonding layer may be formed of a typical bonding agent for polarizing plates well-known to those skilled in the art. For example, the bonding layer may be formed by a water-based bonding agent or a photocurable bonding agent.

The water-based bonding agent may include a polyvinyl alcohol-based bonding resin, a crosslinking agent, and the like.

The photocurable bonding agent may include an epoxy compound and/or a (meth)acrylic compound, and an initiator. The initiator may include a photo-radical initiator and/or a photo-cation initiator, and, in an embodiment, a mixture of a photo-radical initiator and a photo-cation initiator. The photocurable bonding agent may further include typical additives, such as an antioxidant agent, pigments, and the like.

In an embodiment, the bonding layer may have a thickness of 0.05 μm to 10 μm. Within this range, the bonding layer can be used in an optical display apparatus.

Next, a polarizing plate according to another embodiment of the invention will be described.

The polarizing plate according to an embodiment includes a polarizer, a protective film formed on at least one surface of the polarizer, and an adhesive layer formed on a surface of the polarizer or the protective film. In an embodiment, the polarizing plate may include a polarizer, a first protective film formed on an upper surface of the polarizer, a second protective film formed on a lower surface of the polarizer, and an adhesive layer formed on a lower surface of the polarizer.

The polarizing plate may be applied to an optical display apparatus after formation of a hole therein. The hole may correspond to a non-image display region and a region of the polarizing plate other than the hole may correspond to an image display region. FIG. 3 is a cross-sectional view of a polarizing plate according to an embodiment of the present invention after formation of a hole in the polarizing plate.

Referring to FIG. 3, the polarizing plate according to an embodiment includes a polarizer 10, a first protective film 20 stacked on an upper surface of the polarizer 10, a second protective film 30 stacked on a lower surface of the polarizer 10, and an adhesive layer 50 stacked on a lower surface of the second protective film 30, wherein a hole 40 is formed in a region of the polarizing plate. In an embodiment, the hole 40 may be formed perpendicular to a surface (upper or lower surface) of the polarizing plate.

In an embodiment, the polarizing plate has a coefficient of thermal expansion of 100 μm/(m·° C.) or less, as measured after the polarizing plate is left under heat shock conditions. Here, the coefficient of thermal expansion is a value measured with the adhesive layer present in the polarizing plate. Within this range, the polarizing plate can prevent or substantially prevent generation of bubbles in a hole, which is formed having a small diameter in the polarizing plate, and can prevent or substantially prevent observation of bubbles, if any, while preventing or substantially preventing generation of cracks around the hole due to shrinkage of the hole, after application of the heat shock conditions thereto. In an embodiment, the polarizing plate may have a coefficient of thermal expansion of 70 μm/(m·° C.) to 100 μm/(m·° C.), and, in an embodiment, 80 μm/(m·° C.) to 100 μm/(m·° C.), as measured after the polarizing plate is left under the heat shock conditions. Within this range, the polarizing plate can secure the polarization function and can be easily manufactured.

In an embodiment, the polarizer has a thickness of 10 μm or less. The polarizer, the first protective film, and the second protective film may be substantially the same as those of the polarizing plate according to the above-described embodiment.

Thus, the following description will focus on the adhesive layer.

The adhesive layer may be a pressure-sensitive adhesive (PSA) and may adhesively attach the polarizing plate to an adherend, for example, a panel of an optical display apparatus. The adhesive layer may reduce the coefficient of thermal expansion, as compared to the coefficient of thermal expansion of the polarizing plate not including the adhesive layer, whereby the polarizing plate can easily prevent or substantially prevent observation of bubbles in the hole and generation of cracks in the polarizing plate due to shrinkage of the hole after formation of the hole having a small diameter in the polarizing plate.

In an embodiment, the adhesive layer may have a storage modulus of 40 kPa or more at 100° C. and satisfy the following Formula 1:

0<|G2−G1|/G1≤0.1, Formula 1

where, in Formula 1, G1 is storage modulus (unit: kPa) of the adhesive layer at 100° C., and G2 is storage modulus (unit: kPa) of the adhesive layer at 120° C.).

The satisfying of Formula 1 means that the adhesive layer has a low variation rate of storage modulus even at high temperature. Although storage modulus of the adhesive layer decreases with increasing temperature, the adhesive layer according to the present invention allows relatively small decrease in storage modulus at high temperature, as the temperature increases. This means that the adhesive layer has high cohesion at high temperature and allows small variation in cohesion to suppress shrinkage of the polarizing plate formed with the hole having a small diameter as the temperature increases.

As the adhesive layer has a storage modulus of 40 kPa or more at 100° C. while satisfying Formula 1, the polarizing plate can suppress light leakage while preventing or substantially preventing generation of cracks in the polarizing plate due to shrinkage of the hole after formation of the hole having a small diameter in the polarizing plate.

In an embodiment, the adhesive layer may have a storage modulus at 100° C. of 40 kPa, 41 kPa, 42 kPa, 43 kPa, 44 kPa, 45 kPa, 46 kPa, 47 kPa, 48 kPa, 49 kPa, 50 kPa, 51 kPa, 52 kPa, 53 kPa, 54 kPa, 55 kPa, 56 kPa, 57 kPa, 58 kPa, 59 kPa, 60 kPa, 61 kPa, 62 kPa, 63 kPa, 64 kPa, 65 kPa, 66 kPa, 67 kPa, 68 kPa, 69 kPa, or 70 kPa, for example, 40 kPa to 70 kPa.

In an embodiment, the adhesive layer may have a |G2−G1|/G1 value of 0.01 to 0.1, for example, 0.01, 0.02, 0.03, 0.04, 0.05, 0.06, 0.07, 0.08, 0.09, or 0.1. Within this range, the adhesive layer can further improve the effects of the present invention while maintaining adhesive strength thereof.

In an embodiment, the adhesive layer may have a storage modulus at 120° C. of 40 kPa or more, for example, 40 kPa, 41 kPa, 42 kPa, 43 kPa, 44 kPa, 45 kPa, 46 kPa, 47 kPa, 48 kPa, 49 kPa, 50 kPa, 51 kPa, 52 kPa, 53 kPa, 54 kPa, 55 kPa, 56 kPa, 57 kPa, 58 kPa, 59 kPa, 60 kPa, 61 kPa, 62 kPa, 63 kPa, 64 kPa, 65 kPa, 66 kPa, 67 kPa, 68 kPa, 69 kPa, or 70 kPa, for example, 40 kPa to 70 kPa. Within this range, the adhesive layer can easily satisfy Formula 1 while maintaining adhesive strength thereof.

In an embodiment, the adhesive layer may have a thickness of 15 μm or less. Within this range, the adhesive layer can be applied to the polarizing plate while maintaining adhesive strength. In an embodiment, the adhesive layer may have a greater thickness than the polarizer, and, in an embodiment, a thickness of 10 μm to 15 μm.

The adhesive layer may be formed by coating an adhesive composition for the adhesive layer to a certain thickness (e.g., a predetermined thickness) on a release film or a protective film. The adhesive layer may include a cured product of the adhesive composition. Next, the adhesive composition will be described.

The adhesive composition may include a (meth)acrylic-based copolymer, an isocyanate-based curing agent, and a metal chelate-based curing agent.

### (Meth)Acrylic-Based Copolymer

The (meth)acrylic-based copolymer may include a (meth)acrylic-based copolymer of a monomer mixture including an alkyl group-containing (meth)acrylic-based monomer, a crosslinkable functional group-containing (meth)acrylic-based monomer, and a (meth)acrylic-based monomer having a homopolymer glass transition temperature (Tg) of 0° C. or more. Herein, the homopolymer glass transition temperature may be measured by a typical method known to those skilled in the art.

The alkyl group-containing (meth)acrylic-based monomer may include a C₁ to C₂₀ alkyl group-containing (meth)acrylic acid ester. The C₁ to C₂₀ alkyl group-containing (meth)acrylic acid ester may include at least one selected from among ethyl (meth)acrylate, propyl (meth)acrylate, n-butyl (meth)acrylate, iso-butyl (meth)acrylate, pentyl (meth)acrylate, hexyl (meth)acrylate, 2-ethylhexyl (meth)acrylate, heptyl (meth)acrylate, octyl (meth)acrylate, iso-octyl (meth)acrylate, nonyl (meth)acrylate, decyl (meth)acrylate, and dodecyl (meth)acrylate, without being limited thereto. In an embodiment, the alkyl group-containing (meth)acrylic-based monomer may have a homopolymer glass transition temperature of less than 0° C., for example, −80° C. to less than 0° C.

The crosslinkable functional group-containing (meth)acrylic-based monomer may include a hydroxyl group-containing (meth)acrylic-based monomer. The hydroxyl group-containing (meth)acrylic-based monomer may include at least one selected from among a (meth)acrylic-based monomer containing a C₁ to C₂₀ alkyl group having a hydroxyl group, a (meth)acrylic-based monomer containing a C₃ to C₂₀ cycloalkyl group having a hydroxyl group, and a (meth)acrylic-based monomer containing a C₆ to C₂₀ aromatic group having a hydroxyl group. For example, the hydroxyl group-containing (meth)acrylic-based monomer may include at least one selected from among 2-hydroxyethyl (meth)acrylate, 2-hydroxypropyl (meth)acrylate, 2-hydroxybutyl (meth)acrylate, 4-hydroxybutyl (meth)acrylate, 6-hydroxyhexyl (meth)acrylate, 1,4-cyclohexanedimethanol mono(meth)acrylate, 1-chloro-2-hydroxypropyl (meth)acrylate, diethylene glycol mono(meth)acrylate, 2-hydroxy-3-phenyloxypropyl (meth)acrylate, 4-hydroxycyclopentyl (meth)acrylate, and 4-hydroxycyclohexyl (meth)acrylate.

In the (meth)acrylic-based copolymer, the (meth)acrylic-based monomer having a homopolymer glass transition temperature (Tg) of 0° C. or more can secure surface resistance reliability together with an antistatic agent and can maintain peel strength at high temperature or can allow the adhesive layer to exhibit high adhesive strength with respect to an adherend without being peeled off. In an embodiment, the (meth)acrylic-based monomer may have a homopolymer Tg of 3° C. to 150° C., and, in an embodiment, 5° C. to 130° C. The (meth)acrylic-based monomer having a homopolymer glass transition temperature (Tg) of 0° C. or more may include at least one selected from among an alkyl group-containing (meth)acrylic-based monomer and an alicyclic group-containing (meth)acrylic-based monomer, which have a homopolymer glass transition temperature (Tg) of 0° C. or more. For example, the (meth)acrylic-based monomer having a homopolymer glass transition temperature (Tg) of 0° C. or more may include at least one selected from among methyl acrylate, methyl methacrylate, t-butyl acrylate, t-butyl methacrylate, isobornyl acrylate, isobornyl methacrylate, and acryloyl morpholine.

In an embodiment, the monomer mixture may include 40 wt % to 95 wt %, and, in an embodiment, 45 wt % to 80 wt %, of the alkyl group-containing (meth)acrylic-based monomer, 0.01 wt % to 20 wt %, and, in an embodiment, 0.01 wt % to 10 wt %, and, in an embodiment, 0.3 wt % to 4.0 wt %, of the crosslinkable functional group-containing (meth)acrylic-based monomer, and 1 wt % to 40 wt %, and, in an embodiment, 5 wt % to 35 wt %, and, in an embodiment, 5 wt % to 30 wt %, of the (meth)acrylic-based monomer having a homopolymer glass transition temperature (Tg) of 0° C. or more. Within this range, the effects of the present invention can be easily realized.

In an embodiment, the (meth)acrylic-based copolymer may have a glass transition temperature of −50° C. or more, for example, −45° C. to −20° C. Within this range, the effects of the present invention can be easily realized. The (meth)acrylic-based copolymer may have a weight average molecular weight of greater than 1,000,000, for example, 1,100,000 or more, and, in an embodiment, 1,500,000 to 1,800,000. Within this range, the effects of the present invention can be easily realized.

The monomer mixture may further include an aromatic group-containing (meth)acrylic-based monomer.

In the adhesive layer, the aromatic group-containing (meth)acrylic-based monomer can further improve an effect of suppressing light leakage. The aromatic group-containing (meth)acrylic-based monomer is a C₆ to C₂₀ aromatic group-containing (meth)acrylic acid ester and may include at least one selected from among phenoxy ethyl (meth)acrylate, phenyl (meth)acrylate, and benzyl (meth)acrylate.

The monomer mixture may include at least one type of aromatic group-containing (meth)acrylic-based monomer. In the monomer mixture, the aromatic group-containing (meth)acrylic-based monomer may be present in an amount of 1 wt % to 35 wt %, and, in an embodiment, 5 wt % to 25 wt %. Within this range, the polarizing plate can suppress light leakage.

The (meth)acrylic-based copolymer may be prepared through polymerization of the monomer mixture by a typical polymerization method.

### Isocyanate-Based Curing Agent

The isocyanate-based curing agent may improve substrate adhesion and peel strength by curing the (meth)acrylic-based copolymer.

The isocyanate-based curing agent may include a tri- or higher isocyanate curing agent. The tri- or higher isocyanate-based curing agent means a curing agent containing three or more isocyanate groups. In an embodiment, the isocyanate-based curing agent may include a tri- to hexa-functional isocyanate curing agent having 3 to 6 isocyanate groups. The tri- or higher isocyanate curing agent can increase the crosslinking rate through reaction with a hydroxyl group of the (meth)acrylic-based copolymer and can increase reliability and the ratio of substrate adhesion to peel strength of the adhesive film through improvement in substrate adhesion. In an embodiment, the tri- or higher isocyanate-based curing agent may include any of trifunctional isocyanate curing agents including a trifunctional trimethylolpropane modified toluene diisocyanate adduct, a trifunctional toluene diisocyanate trimer, a trimethylolpropane modified xylene diisocyanate adduct, and the like, and polyfunctional isocyanate curing agents including a hexafunctional trimethylolpropane modified toluene diisocyanate, a hexafunctional isocyanurate modified toluene diisocyanate, and the like. In an embodiment, the tri- or higher isocyanate curing agent may be a trifunctional isocyanate curing agent having an aromatic group and a isocyanurate group, and, in an embodiment, a toluene diisocyanate trimer. For example, the tri- or higher isocyanate-based curing agent may be Coronate-2030 (Nippon Polyurethane Co., Ltd.).

In an embodiment, the isocyanate-based curing agent may be present in an amount of 0.01 parts by weight to 5 parts by weight, for example, 0.05 parts by weight to 1 part by weight, relative to 100 parts by weight of the (meth)acrylic-based copolymer. Within this range, the isocyanate-based curing agent can reduce aging duration of the adhesive composition while improving substrate adhesion and durability of the polarizing plate.

### Metal Chelate-Based Curing Agent

The metal chelate-based curing agent serves to improve the crosslinking rate through reaction with the (meth)acrylic-based copolymer.

The metal chelate-based curing agent may include a typical metal chelate-based curing agent. For example, the metal chelate-based curing agent may be a curing agent containing a metal, such as aluminum, titanium, iron, copper, zinc, tin, titanium, nickel, antimony, magnesium, vanadium, chromium, and zirconium. For example, the metal chelate-based curing agent may include at least one selected from among aluminum ethyl acetoacetate diisopropylate, aluminum tris(ethyl acetoacetate), alkyl acetoacetate aluminum diisopropylate, aluminum isopropylate, mono-sec-butoxyaluminum diisopropylate, aluminum-sec-butyrate, aluminum ethylate, tetra-isopropyl titanate, tetra-normal butyl titanate, butyl titanate dimer, titanium acetyl acetonate, titanium octylene glycolate, titanium tetra-acetyl acetonate, titanium ethyl acetate, polyhydroxytitanium stearate, and aluminum acetyl acetonate. In an embodiment, a metal chelate-based curing agent containing an acetyl acetonate group allows rapid evaporation of the acetyl acetonate group from the curing agent upon drying an adhesive film, which is formed by coating and drying the adhesive composition, and can increase the curing rate of the (meth)acrylic-based copolymer to reduce a process time through reduction in aging duration of the adhesive film.

In an embodiment, the metal chelate-based curing agent may be present in a smaller amount than the isocyanate-based curing agent, for example, in an amount of 0.01 parts by weight to 5 parts by weight, for example, 0.05 parts by weight to 1 part by weight, relative to 100 parts by weight of the (meth)acrylic-based copolymer. Within this range, the metal chelate-based curing agent can reduce aging duration of the adhesive film while improving durability.

In an embodiment, the isocyanate-based curing agent and the metal chelate-based curing agent may be present in a total amount of 90 wt % or more, for example, 95 wt % to 100 wt %, based on the total amount of all curing agents contained in the adhesive composition. Within this range, the effects of the present invention can be easily realized.

The adhesive composition may further include a silane coupling agent. The silane coupling agent may include a typical silane coupling agent known to those skilled in the art. For example, the silane coupling agent may include an epoxy group-containing silane coupling agent, such as glycidoxypropyltrimethoxysilane and glycidoxypropylmethyldimethoxysilane, without being limited thereto.

In an embodiment, the silane coupling agent may be present in an amount of 0.01 parts by weight to 5 parts by weight relative to 100 parts by weight of the (meth)acrylic-based copolymer. Within this range, the silane coupling agent can improve adhesive strength of the adhesive composition.

The adhesive composition may further include additives. The additives serve to impart additional functions to an adhesive film. The additives may include at least one selected from an antistatic agent, a UV absorber, a reaction inhibitor, an adhesion improver, a thixotropic agent, a conductivity imparting agent, a color adjusting agent, a stabilizer, an antioxidant, and a leveling agent, without being limited thereto.

Next, an optical display apparatus according to an embodiment of the present invention will be described.

The optical display apparatus according to an embodiment may include the polarizer or the polarizing plate according to an embodiment of the present invention. The optical display apparatus may include a liquid crystal display and/or a light emitting element display. The light emitting element display includes an organic or inorganic light emitting diode as the light emitting element, which may mean an element including any of a light emitting diode (LED), an organic light emitting diode (OLED), a quantum dot light emitting diode (QLED), a light emitting material such as phosphors, and the like.

Next, the present invention will be described in further detail with reference to some examples. However, it is to be understood that these examples are provided for illustration and should not be construed in any way as limiting the invention.

### Example 1

### (1) Preparation of Polarizer

A polyvinyl alcohol-based film (TS-#2000, Nippon Kuraray Co., Ltd., containing hydrophobic functional group in main chain, thickness: 20 μm, softening point: 68° C., tensile strength (@25° C.): 98 MPa) washed with water being in the state of 25° C. was subjected to swelling with water in a swelling bath being in the state of 30° C.

The film having passed through the swelling bath was dyed in a dyeing bath, which receives an aqueous solution containing 1 mol/ml of potassium iodide and 1 wt % of boric acid and being in the state of 30° C., for 65 seconds. The film having passed through the dyeing bath was stretched to 5.7 times an initial length thereof in a wet stretching bath, which receives an aqueous solution containing 3 wt % of boric acid and being in the state of 60° C. The film having passed through the wet stretching bath was treated in a crosslinking bath, which receives an aqueous solution containing 3 wt % of boric acid and being in the state of 25° C., for 65 seconds.

Next, the film was treated in a color correction bath containing an aqueous solution containing 4.5 wt % of potassium iodide and being in the state of 30° C., for 10 seconds. A polarizer (thickness: 7 μm, boric acid content: 20 wt %) was prepared by washing the film with water, followed by drying.

### (2) Preparation of Polarizing Plate

A polarizing plate was prepared by coating a water-based bonding agent (containing a polyvinyl alcohol resin) on both surfaces of the prepared polarizer and bonding a triacetylcellulose (TAC) film (thickness: 30 μm, FujiTAC, Fuiji Inc.) and a triacetylcellulose (TAC) film (thickness: 20 μm, FujiTAC, Fuiji Inc.) to upper and lower surfaces of the polarizer, respectively.

### Example 2 to Example 5

Polarizers and polarizing plates were prepared in the same manner as in Example 1 except that the content of components in each of the dyeing bath, the stretching bath, and the crosslinking bath was changed together with the stretching temperature, the stretching ratio, and the kind of protective film.

### Example 6

### Formation of Adhesive Layer

In a 1 L reactor equipped with a cooler for easy temperature regulation under a nitrogen purging condition, a monomer mixture comprising 69 parts by weight of n-butylacrylate (BA), 1 part by weight of 4-hydroxybutyl acrylate (4-HBA), 10 parts by weight of methyl acrylate (MA), and 20 parts by weight of phenoxy ethyl acrylate was placed, followed by adding 100 parts by weight of ethyl acetate as a solvent thereto. Thereafter, the reactor was purged with nitrogen gas to remove oxygen and maintained at 62° C. An acrylic copolymer having a weight average molecular weight of 1,690,000 g/mol was prepared by evenly stirring the monomer mixture and adding 0.03 parts by weight of azobisisobutyronitrile (AIBN) as a reaction initiator, followed by reaction for 8 hours.

An adhesive composition was prepared by adding 0.3 parts by weight of an isocyanate-based curing agent (Coronate-2030S, Nippon Polyurethane Co., Ltd.), 0.02 parts by weight of aluminum acetyl acetonate (Sigma Aldrich, a metal chelate based curing agent), and 0.1 parts by weight of a silane coupling agent (3-glycidoxypropyltrimethoxysilane (KBM-403, Shin-Etsu Chemical Industry Co., Ltd.) to 100 parts by weight of the prepared acrylic copolymer, diluting the resulting mixture to a suitable concentration in consideration of coatability, and uniformly blending the resulting mixture.

An adhesive layer (thickness: 12 μm) was prepared by coating the prepared adhesive composition to a predetermined thickness on a surface of a polyethylene terephthalate (PET) film used as a release film, followed by drying.

### Preparation of Polarizing Plate

A polarizing plate was prepared by removing the release film from the prepared adhesive layer and attaching the adhesive layer to a lower surface of a 20 μm triacetylcellulose film of the polarizing plate prepared in Example 1.

### Example 7

A polarizing plate was prepared in the same manner as in Example 6 except that 0.4 parts by weight of an isocyanate curing agent (Coronate-20305, Nippon Polyurethane Co., Ltd.) and 0.03 parts by weight of aluminum acetyl acetonate (Sigma Aldrich) were used.

### Comparative Example 1

A polyvinyl alcohol-based film (PE-#3000, Nippon Kuraray Co., Ltd., not containing hydrophobic functional group in main chain, thickness: 30 μm) washed with water being in the state of 25° C. was subjected to swelling with water in a swelling bath being in the state of 30° C.

The film having passed through the swelling bath was dyed in a dyeing bath, which receives an aqueous solution containing 1 mol/ml of potassium iodide and 1 wt % of boric acid and being in the state of 30° C., for 65 seconds. The film having passed through the dyeing bath was stretched to 5.7 times an initial length thereof in a wet stretching bath, which receives an aqueous solution containing 3 wt % of boric acid and being in the state of 53° C. The film having passed through the wet stretching bath was treated in a crosslinking bath, which receives an aqueous solution containing 3 wt % of boric acid and being in the state of 25° C., for 65 seconds.

Next, the film was treated in a color correction bath containing an aqueous solution containing 4.5 wt % of potassium iodide and being in the state of 30° C., for 10 seconds. A polarizer (thickness: 12 μm) was prepared by washing the film with water, followed by drying.

A polarizing plate was prepared using the prepared polarizer in the same manner as in Example 1.

### Comparative Example 2

A 12 μm thick polarizer was prepared using a polyvinyl alcohol-based film (TS-#3000, Nippon Kuraray Co., Ltd., containing hydrophobic functional group in main chain, thickness: 20 μm, softening point: 66° C., tensile strength (@25° C.): 98 MPa) by changing the stretching ratio and the stretching temperature in Example 1. A polarizing plate was prepared using the prepared polarizer in the same manner as in Example 1.

### Comparative Example 3

A polyvinyl alcohol-based film (TS-#3000, Nippon Kuraray Co., Ltd., containing hydrophobic functional group in main chain, thickness: 20 μm, softening point: 66° C., tensile strength (@25° C.): 98 MPa) was used. An attempt was made to prepare a 10 μm thick polarizer by changing the stretching ratio and the stretching temperature in Example 1. However, the 10 μm thick polarizer could not be prepared due to fracture of the polyvinyl alcohol film during the stretching process.

### Comparative Example 4

A polyvinyl alcohol-based film (TS-#3000, Nippon Kuraray Co., Ltd., containing hydrophobic functional group in main chain, thickness: 20 μm, softening point: 66° C., tensile strength (@25° C.): 98 MPa) was used. An attempt was made to prepare a 7 μm thick polarizer by changing the stretching ratio and the stretching temperature in Example 1. However, the 7 μm thick polarizer could not be prepared due to fracture of the polyvinyl alcohol film during the stretching process.

### Comparative Example 5

A polyvinyl alcohol-based film (TS-#2000, Nippon Kuraray Co., Ltd., containing hydrophobic functional group in main chain, thickness: 20 μm, softening point: 68° C., tensile strength (@25° C.): 98 MPa) washed with water being in the state of 25° C. was subjected to swelling with water in a swelling bath being in the state of 30° C.

The film having passed through the swelling bath was dyed in a dyeing bath, which receives an aqueous solution containing 1 mol/ml of potassium iodide and 2.5 wt % of boric acid and being in the state of 30° C., for 65 seconds. The film having passed through the dyeing bath was stretched to 5.7 times an initial length thereof in a wet stretching bath, which receives an aqueous solution containing 6 wt % of boric acid and being in the state of 60° C. The film having passed through the wet stretching bath was treated in a crosslinking bath, which receives an aqueous solution containing 6 wt % of boric acid and being in the state of 25° C., for 65 seconds.

Next, the film was treated in a color correction bath containing an aqueous solution containing 4.5 wt % of potassium iodide and being in the state of 30° C., for 10 seconds. A polarizer (thickness: 7 μm, boric acid content: 35 wt %) was prepared by washing the film with water, followed by drying.

A polarizing plate was prepared using the prepared polarizer in the same manner as in Example 1.

The polarizing plates prepared in the Examples and Comparative Examples were evaluated as to the following properties, and evaluation results are shown in Table 1.

(1) Coefficient of thermal expansion 1 (unit: μm/(m·° C.)): The coefficient of thermal expansion was measured through thermomechanical analysis (TMA). Each of the polarizing plates prepared in Examples 1 to 5 and Comparative Examples 1 and 2 was cut into a sample having a size of 8 mm×5 mm (MD×TD of polarizer) and subjected to heat shock under the following conditions. Thereafter, the sample was heated from 25° C. to 80° C. at a heating rate of 5° C./min under a load of 0.02 N to 0.05 N applied in the stretching direction of the polarizer (in the MD of the polarizer) under a nitrogen atmosphere, followed by measuring the coefficient of thermal expansion in the machine direction of the polarizer. The coefficient of thermal expansion 1 of each of the polarizing plates of Examples 6 and 7 was measured in the same manner, with the adhesive layer formed on the polarizing plate.

### Heat Shock Condition

Heating the polarizing plate from 25° C. to 80° C. at a heating rate of 5° C./min; →cooling the polarizing plate from 80° C. to −40° C. at a cooling rate of 5° C./min; heating the polarizing plate from −40° C. to 80° C. at a heating rate of 5° C./min; cooling the polarizing plate from 80° C. to −40° C. at a cooling rate of 5° C./min; heating the polarizing plate from −40° C. to 80° C. at a heating rate of 5° C./min; and cooling the polarizing plate from 80° C. to −40° C. at a cooling rate of 5° C./min.

(2) Coefficient of thermal expansion 2 (unit: μm/(m·° C.)): The coefficient of thermal expansion was measured through thermomechanical analysis (TMA). Each of the polarizing plates prepared in the Examples and Comparative Examples was cut into a sample having a size of 8 mm×5 mm (MD×TD of polarizer). Thereafter, the sample was heated from 25° C. to 80° C. at a heating rate of 5° C./min under a load of 0.02 N to 0.05 N applied in the stretching direction of the polarizer (in the MD of the polarizer) under a nitrogen atmosphere, followed by measuring the coefficient of thermal expansion. The coefficient of thermal expansion 2 of each of the polarizing plates of Examples 6 and 7 was measured in the same manner, with the adhesive layer formed on the polarizing plate.

(3) Bubble generation in hole 1: A glass substrate 1 (0.5T), an optically clear adhesive 2 (OCA, 3M, OCA-8371), and polarizing plates 3 (MD×TD of polarizer, 70 mm×150 mm) of the Examples and Comparative Examples, each of which was formed with a hole 6 (circular shape having a diameter of 4 mm, formed by punching), were prepared and a sample having a cross-section shown in FIG. 4 was prepared by sequentially attaching an OCA 4 (Optically Clear Adhesive, 3M, OCA-8371) and a glass substrate 5 (0.5T) to each of the polarizing plates 3. Generation of bubbles around the hole of the sample was observed through an optical micrograph.

When bubbles formed around the hole have a size of 100 μm or less, the bubbles are blocked by a black matrix around the hole in a display apparatus and thus cannot be observed with the naked eye of a user. Here, even in the case in which several bubbles are connected around the hole to form an elongated hole having a length of 100 μm or less in an outward direction from the center of the hole, the bubbles cannot be observed for the same reason. Hole generation was evaluated according to the following criteria.

1: Bubbles formed around the hole had a size of 100 μm or less and were not observed at all.

2: Bubbles formed around the hole had a size of 100 μm or less and were very slightly observed.

3: Bubbles formed around the hole had a size of 100 μm or less and were slightly observed.

4: Bubbles formed around the hole had a size of greater than 100 μm and were significantly observed.
5: Bubbles formed around the hole had a size of greater than 100 μm and were very significantly observed.

(4) Bubble generation in hole 2: A glass substrate (0.5T), an optically clear adhesive (OCA, 3M, OCA-8371), and polarizing plates (MD×TD of polarizer, 70 mm×150 mm) of the Examples and Comparative Examples, each of the polarizing plates was formed with a hole (circular shape having a diameter of 4 mm, formed by punching), were prepared and a sample was prepared by sequentially attaching the OCA (Optically Clear Adhesive, 3M, OCA-8371) and the glass substrate (0.5T) to each of the polarizing plates.

The sample was subjected to 100 cycles of heat shock, in which one cycle refers to an operation of leaving the sample at −40° C. for 30 minutes and leaving the sample at 80° C. for 30 minutes, followed by observing generation of bubbles around the hole through the optical microscope. Bubble generation was evaluated in the same manner as in (3).

(5) Crack generation: Some samples were prepared in the same manner as in (4). Some samples were prepared in the same manner as in (4) except that a hole was not formed therein. The prepared samples were subjected to heat shock under the same conditions as in (4). The length of the largest crack formed in the polarizing plate in the MD of the polarizer was evaluated through a microscope. A sample having a maximum crack length of 200 μm or more was rated as ◯ and a sample having a maximum crack length of less than 200 μm was rated as X.

(6) Storage modulus of adhesive layer (unit: kPa): A 0.8 mm thick specimen was prepared by stacking 12 μm thick adhesive layers, followed by measuring storage modulus at 100° C. and at 120° C. using an advanced rheometry expansion system (ARES, TA Instrument) through temperature sweep testing (strain 5%, normal force 100 N) while heating the sample from 0° C. to 150° C. at a heating rate of 10° C./min at 1 Hz.

TABLE 1

| | | | | | | | | | Comparative | | |
|---|---|---|---|---|---|---|---|---|---|---|---|
| | | Example | | | | | | | Example | | |
| | | 1 | 2 | 3 | 4 | 5 | 6 | 7 | 1 | 2 | 5 |
| Kind of PVA | | TS- | TS- | TS- | TS- | TS- | TS- | TS- | PE- | TS- | TS- |
| film | | #2000 | #2000 | #2000 | #2000 | #2000 | #2000 | #2000 | #3000 | #3000 | #2000 |
| Stretching | | 60 | 60 | 57 | 57 | 57 | 57 | 57 | 53 | 60 | 60 |
| Temp (° C.) | | | | | | | | | | | |
| Stretching ratio | | 5.7 | 5.7 | 5.7 | 5.7 | 5.7 | 5.7 | 5.7 | 5.7 | 5.9 | 5.7 |
| Polarizer | | 7 | 7 | 7 | 7 | 7 | 7 | 7 | 12 | 12 | 7 |
| thickness (μm) | | | | | | | | | | | |
| First protective | | TAC | TAC | TAC | PET | COP | TAC | TAC | TAC | TAC | TAC |
| film | | | | | | | | | | | |
| Second | | TAC | TAC | TAC | TAC | TAC | TAC | TAC | TAC | TAC | TAC |
| protective film | | | | | | | | | | | |
| Storage | | — | — | — | — | — | 45 | 63 | — | — | — |
| modulus | | | | | | | | | | | |
| (@100° C.) | | | | | | | | | | | |
| Storage | | — | — | — | — | — | 49 | 65 | — | — | — |
| modulus | | | | | | | | | | | |
| (@120° C.) | | | | | | | | | | | |
| \|G2 − G1\|/G1 | | — | — | — | — | — | 0.08 | 0.03 | — | — | — |
| Coefficient of | | 99.5 | 97.2 | 98.5 | 86.4 | 87.1 | 96.9 | 97.5 | 110.3 | 108.4 | 125.6 |
| thermal | | | | | | | | | | | |
| expansion 1 | | | | | | | | | | | |
| Coefficient of | | 12.3 | 11.7 | 11.9 | 12.7 | 12.1 | 12.5 | 11.5 | 11.7 | 12.0 | 30.8 |
| thermal | | | | | | | | | | | |
| expansion 2 | | | | | | | | | | | |
| Generation of | | 2 | 2 | 2 | 2 | 2 | 1 | 1 | 5 | 5 | 2 |
| bubble in hole 1 | | | | | | | | | | | |
| Generation of | | 2 | 2 | 2 | 2 | 2 | 1 | 1 | 5 | 5 | 5 |
| bubble in hole 2 | | | | | | | | | | | |
| Crack | Hole | X | X | X | X | X | X | X | ◯ | ◯ | ◯ |
| of | formed | | | | | | | | | | |
| polarizing | Hole | X | X | X | X | X | X | X | ◯ | ◯ | ◯ |
| plate | not | | | | | | | | | | |
| | formed | | | | | | | | | | |

*PET film: Polyethylene terephthalate film (TA044, Toyobo Co., Ltd.)
*COP film: Cyclic olefin polymer film (ZB12-052125, Zeon Co., Ltd.)

As shown in Table 1, the polarizing plates according to the present invention prevented generation of bubbles in the hole or minimized observation of the bubbles in the hole, when the polarizing plate was formed with the hole having a small diameter. In addition, the polarizing plates according to the present invention including a thin polarizer prevented generation of bubbles in the hole or minimized observation of the bubbles in the hole after heat shock, when the polarizing plate was formed with the hole having a small diameter and was attached to an adhesive film. The polarizing plates according to the present invention did not allow generation of cracks after application of heat shock thereto, regardless of formation of a hole having a small diameter therein.

Conversely, the polarizing plates of the Comparative Examples did not provide all effects of the present invention.

While some embodiments have been described herein, it is to be understood that various modifications, changes, alterations, and equivalent embodiments can be made by those skilled in the art without departing from the spirit and scope of the invention.

What is claimed is:

1. A polarizing plate comprising: a polarizer and a protective film formed on a surface of the polarizer,
wherein the polarizer has a thickness of 10 μm or less, and the polarizing plate has a coefficient of thermal expansion (CTE) of 100 μm/(m·° C.) or less, as measured in a machine direction of the polarizer, after the polarizing plate is left under the following heat shock conditions:
heating the polarizing plate from 25° C. to 80° C. at a heating rate of 5° C./min;
cooling the polarizing plate from 80° C. to −40° C. at a cooling rate of 5° C./min;
heating the polarizing plate from −40° C. to 80° C. at a heating rate of 5° C./min;
cooling the polarizing plate from 80° C. to −40° C. at a cooling rate of 5° C./min;
heating the polarizing plate from −40° C. to 80° C. at a heating rate of 5° C./min; and
cooling the polarizing plate from 80° C. to −40° C. at a cooling rate of 5° C./min.

2. The polarizing plate according to claim 1, wherein the polarizer comprises a polyvinyl alcohol-based film, and the polyvinyl alcohol film contains both a hydrophilic functional group and a hydrophobic functional group.

3. The polarizing plate according to claim 1, wherein the polarizer comprises a polyvinyl alcohol-based film, and the polyvinyl alcohol film has a softening point of 66° C. to 70° C.

4. The polarizing plate according to claim 1, wherein the coefficient of thermal expansion of the polarizer measured under the heat shock conditions is in a range of 50% to 250% of the coefficient of thermal expansion of the polarizing plate measured under the heat shock conditions.

5. The polarizing plate according to claim 1, wherein the polarizer has a boric acid content of 15 wt % to 30 wt %.

6. The polarizing plate according to claim 1, wherein the polarizing plate has a coefficient of thermal expansion of 20 μm/(m·° C.) or less, as measured before the polarizing plate is left under the heat shock conditions.

7. The polarizing plate according to claim 1, wherein the protective film has a coefficient of thermal expansion of 40 μm/(m·° C.) or more, as measured after the polarizing plate is left under the heat shock conditions.

8. The polarizing plate according to claim 7, wherein the protective film comprises a triacetylcellulose, polyethylene terephthalate, or amorphous cyclic polyolefin resin film.

9. The polarizing plate according to claim 1, further comprising:
an adhesive layer formed on a surface of the protective film,
the adhesive layer having a storage modulus at 100° C. of 40 kPa or more and satisfying the following Formula 1:
0<|G2−G1|/G1≤0.1,
where, in Formula 1,
G1 is a storage modulus (unit: kPa) of the adhesive layer at 100° C., and
G2 is a storage modulus (unit: kPa) of the adhesive layer at 120° C.

10. The polarizing plate according to claim 9, wherein the adhesive layer has a storage modulus of 40 kPa or more at 120° C.

11. The polarizing plate according to claim 9, wherein the adhesive layer comprises a cured product of a composition comprising a (meth)acrylic-based copolymer, an isocyanate-based curing agent, and a metal chelate-based curing agent.

12. The polarizing plate according to claim 11, wherein the (meth)acrylic-based copolymer is a copolymer of a monomer mixture comprising 40 wt % to 95 wt % of an alkyl group-containing (meth)acrylic-based monomer, 0.01 wt % to 20 wt % of a crosslinkable functional group-containing (meth)acrylic-based monomer, 1 wt % to 40 wt % of a (meth)acrylic-based monomer having a homopolymer glass transition temperature (Tg) of 0° C. or more, and 1 wt % to 35 wt % of an aromatic group-containing (meth)acrylic-based monomer.

13. The polarizing plate according to claim 11, wherein the composition comprises 100 parts by weight of the (meth)acrylic-based copolymer, 0.01 parts by weight to 5 parts by weight of the isocyanate-based curing agent, and 0.01 parts by weight to 5 parts by weight of the metal chelate-based curing agent.

14. The polarizing plate according to claim 1, wherein a hole is formed in at least a region of the polarizing plate in an in-plane direction to penetrate through the polarizing plate in a thickness direction thereof.

15. The polarizing plate according to claim 14, wherein the hole has a diameter of 4 mm or less.

16. An optical display apparatus comprising the polarizing plate according to claim 1.
